(19) United States
(12) Patent Application Publication
(10) Pub. No.: US 2009/0009965 A1
(43) Pub. Date: Jan. 8, 2009

(54) HEAT DISSIPATING STRUCTURE OF MICROCOMPUTER

(76) Inventor: Ta-Yang CHENG, Taipei (TW)

Correspondence Address: BIRCH STEWART KOLASCH & BIRCH, PO BOX 747, FALLS CHURCH, VA, 22040-0747, US

(21) Appl. No.: 11/772,632

(22) Filed: Jul. 2, 2007

(51) Int. Cl. H05K 7/20

(52) U.S. Cl. 361/695; 165/80.3

(57) ABSTRACT

A heat dissipating structure of a microcomputer includes a retaining board; a heat dissipating unit installed on the retaining board and having at least one heat conducting portion disposed on a side of the retaining board and a heat dissipating fin module installed between the heat conducting portions and having a plurality of passage portions; and an air guide unit being a cross flow fan and having an air outlet corresponding to the passage portion of the heat dissipating fin module, such that the heat dissipating structure can be applied in a microcomputer for dissipating a heat source rapidly by the heat dissipating unit in conformity with the air guide unit, so to achieve a better heat dissipating effect

### FIELD OF THE INVENTION

The present invention relates to a heat dissipating structure of a microcomputer, and more particularly to a heat dissipating structure capable of dispersing a heat source rapidly to achieve a better heat dissipating effect.

### BACKGROUND OF THE INVENTION

In a conventional heat dissipating structure of a microcomputer, a heat dissipating fin module is generally installed at a central processing unit on a motherboard, and the heat dissipating fin module is attached onto the central processing unit, and an axial flow fan is installed at the top of the heat dissipating fin module. The method of dissipating heat is to use the heat dissipating fin module to absorb the hot air produced by the central processing unit and expand the area of heat source, and then the axial flow fan produces airflow from the top to the heat dissipating fin module, so that the hot air of the heat dissipating fin flows in different directions to achieve the heat dissipating effect.

Since the interior of a computer casing is a closed space, and the central processing unit on the motherboard as well as other components produce a heat source during their operation, the method of using an axial flow fan to produce airflow to the heat dissipating fin module and drive the hot air of the heat dissipating fin to flow in different directions cannot discharge the hot air directly and completely out of the computer casing, and some of the hot air remain circulating inside the compute casing, and thus such method just recycles the hot air in the close space of the computer casing only, and the heat dissipating effect is poor. As a result, a full heat dissipation function cannot be achieved, and most of the time the central processing unit has a low operating performance or even causes a system breakdown due to the excessively high temperature.

In view of the foregoing shortcomings of the prior art, the inventor of the present invention based on years of experience to conduct extensive researches and experiments, and finally developed a heat dissipating structure of a microcomputer in accordance with the present invention.

### SUMMARY OF THE INVENTION

It is a primary objective of the present invention to design a heat dissipating structure of a microcomputer to overcome the shortcomings of the prior art.

To achieve the foregoing objective, the present invention provides a heat dissipating structure applied in a microcomputer, wherein a heat conducting portion of a heat dissipating unit conducts a heat source to a casing of the microcomputer, and meanwhile an air guide unit guides air to a heat dissipating fin module of the heat dissipating unit for dissipating heat, so as to disperse the heat source rapidly and achieve a better heat dissipating effect.

To achieve the foregoing objective, the present invention provides a heat dissipating structure of a microcomputer, comprising a retaining board; a heat dissipating unit installed on the retaining board and having at least one heat conducting portion disposed on a side of the retaining board, and a heat dissipating fin module disposed between the heat conducting portions and having a plurality of passage portions; and an air guide unit, being a cross flow fan and having an air outlet corresponding to the passage portion of the heat dissipating fin module.

The above and other objects, features and advantages of the present invention will become apparent from the following detailed description taken with the accompanying drawings.

### BRIEF DESCRIPTION OF THE DRAWINGS

FIG. 1 is a perspective view of the present invention;

FIG. 2 is an exploded view of the present invention;

FIG. 3 is a schematic view of assembling the present invention;

FIG. 4 is a schematic view of an assembled structure of the present invention;

FIG. 5 is a schematic view of an assembled heat dissipating structure connected to a casing in accordance with the present invention;

FIG. 6 is a schematic view of a heat dissipating status in accordance with the present invention;

FIG. 7 is a schematic view of another heat dissipating status in accordance with the present invention; and

FIG. 8 is a schematic view of another assembled heat dissipating structure connected to a casing in accordance with the present invention.

### DETAILED DESCRIPTION OF THE PREFERRED EMBODIMENTS

To make it easier for our examiner to understand the objective, innovative features and performance of the present invention, we use preferred embodiments and the accompanying drawings for a detailed description of the present invention.

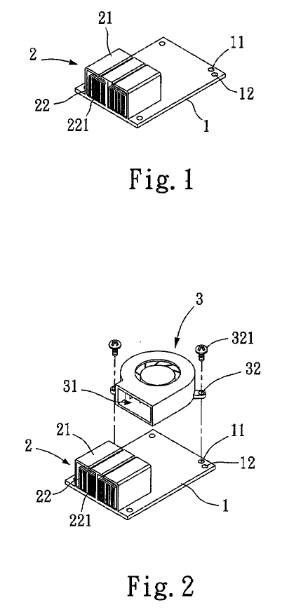

Referring to FIGS. 1 and 2 for a perspective view and an exploded view of the present invention, a heat dissipating structure of a microcomputer in accordance with the present invention comprises a retaining board 1, a heat dissipating unit 2 and an air guide unit 3, and the heat dissipating structure can be applied in a microcomputer, such that the heat dissipating unit can work together with the air guide unit to disperse a heat source rapidly and achieve a better heat dissipating effect.

The retaining board 1 includes a plurality of fixing holes 11, 12 disposed thereon, and the heat dissipating unit 2 is installed on the retaining board 1, and the heat dissipating unit 2 includes at least one heat conducting portion 21 on a side of the retaining board 1, and a heat dissipating fin module 22 having a plurality of passage portions 221 and disposed between the heat conducting portions 21, and the retaining board 1, the heat conducting portion 21 and the heat dissipating fin module 22 are integrated as a whole as needed.

The air guide unit 3 is a cross flow fan installed on the retaining board 1 (or directly mounted onto the motherboard). The air guide unit 3 can be installed to an upper casing, if the casing is designed with an upper casing and a lower casing engaged with each other, and an air outlet 31 of the air guide unit 3 corresponds to a passage portion 221 of the heat dissipating fin module 22, and the periphery of the air guide unit 3 has a latching ear 32 in conformity with the fixing element 321 and the retaining board 1 for fixing the corresponding fixing hole 11. The foregoing structure constitutes a novel heat dissipating structure of a microcomputer.

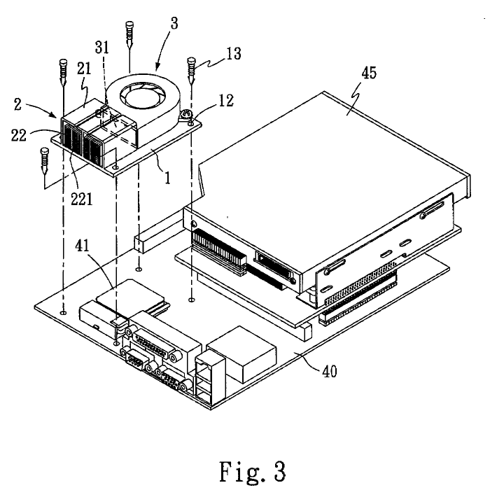

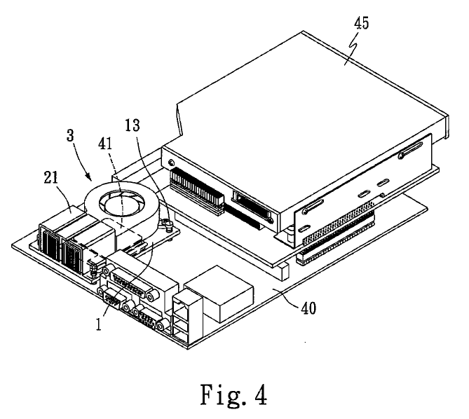

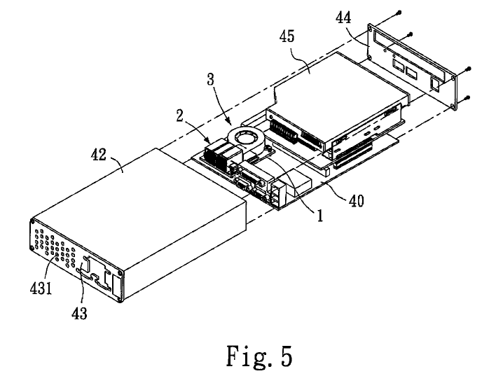

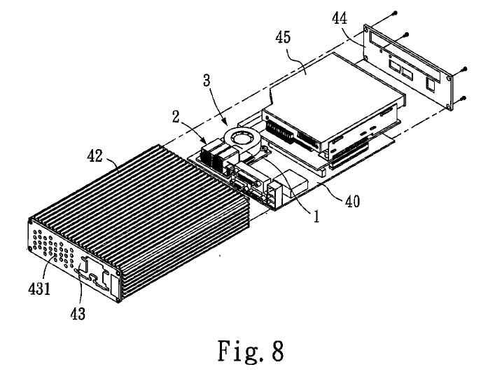

Referring to FIGS. 3 to 5 for a schematic view of assembling the present invention, a schematic view of an assembled structure of the present invention, and a schematic view of an assembled structure connected to a casing in accordance with the present invention respectively, a retaining board 1 is installed on a central processing unit (CPU) 41 of a motherboard 40 in a microcomputer 4, and a plurality of fixing elements 13 in conformity with other fixing holes 12 on the retaining board 1 are fixed with the motherboard 40, so that the bottom of the retaining board 1 is attached to the central processing unit 41, and the motherboard 40 is installed in a casing 42, such that a heat conducting portion 21 of the heat dissipating unit 2 is in contact with an internal surface of the casing 42, and a passage portion 221 of the heat dissipating fin module 22 corresponds with a through hole 431 of a rear panel 43, and a front panel 44 is disposed at the front side of the casing 42, so as to complete assembling the heat dissipating structure of the present invention. Referring to FIG. 8 for a schematic view of another assembled heat dissipating structure connected to a casing in accordance with the present invention, an external surface of the microcomputer 4 can be designed to include the heat dissipating fins for expediting the heat dissipation.

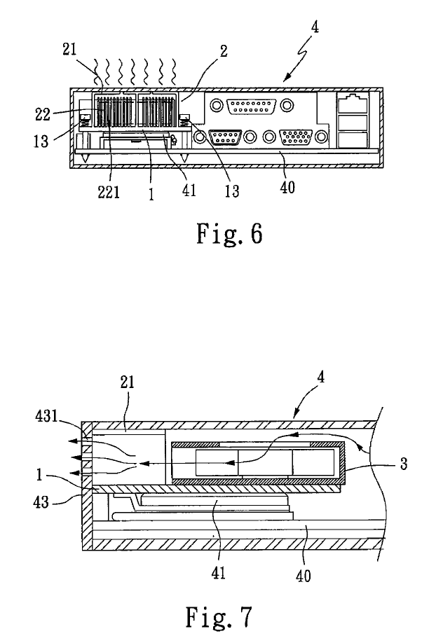

Referring to FIGS. 6 and 7 respectively for schematic views of two heat dissipating statuses in accordance with the present invention, related electronic components such as the central processing unit 41 and the storage unit 45 in the microcomputer 4 will produce a heat source, after the microcomputer 4 is started, and the retaining board 1 absorbs the heat source of the central processing unit 41, and in the meantime, the heat conducting portion 21 of the heat dissipating unit 2 and the heat dissipating fin module 22 absorbs the heat source on the retaining board 1, and the heat conducting portion 21 is used for conducting the heat source to the casing 42, such that the heat source can be dispersed by means of the contact of the casing 42 with the external environment. In the meantime, the air guide unit 3 guides the produced air from an air outlet 31 to the passage portion 221 of the heat dissipating fin module 22. When the air guide unit 3 guides the air, the hot air produced by other equipments or related electronic components in the casing 42 is carried away at the same time, and the hot air is discharged from the passage portion 221 of the heat dissipating fin module 22 towards a through hole 431 of the rear panel 43. With the air guide unit 3 and the passage portion 221 of the heat dissipating fin module 22, the heat source is discharged from the casing 42. Therefore, the heat dissipating unit 2 in conformity with the air guide unit 3 can provide a better heat dissipating effect.

In summation of the description above, the heat dissipating structure of a microcomputer in accordance with the present invention can overcome the shortcomings of the prior art, and the heat dissipating structure can be applied in a microcomputer, so that the heat dissipating unit can conduct the heat source to the microcomputer for the heat dissipation. In the meantime, the air guide unit is used for guiding air to the heat dissipating unit for the heat dissipation, so as to disperse the heat source rapidly and achieve a better heat dissipating effect.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A heat dissipating structure of a microcomputer, comprising:
a retaining board;
a heat dissipating unit, installed on the retaining board, and having at least one heat conducting portion disposed on a side of the retaining board, and a heat dissipating fin module disposed between the heat conducting portions and having a plurality of passage portions; and
an air guide unit, being a cross flow fan, and having an air outlet corresponding to the passage portion of the heat dissipating fin module.

2. The heat dissipating structure of a microcomputer as recited in claim 1, wherein the retaining board includes a plurality of fixing holes thereon.

3. The heat dissipating structure of a microcomputer as recited in claim 1, wherein the retaining board, the heat conducting portion and the heat dissipating fin module are integrated as a whole.

4. The heat dissipating structure of a microcomputer as recited in claim 1, wherein the air guide unit includes a latching car disposed at the periphery of the air guide unit and connected to the retaining board in conformity with the fixing element.

5. The heat dissipating structure of a microcomputer as recited in claim 1, wherein the air guide unit is disposed on the retaining board.
